(19) United States
(12) Patent Application Publication
(10) Pub. No.: US 2006/0292716 A1
(43) Pub. Date: Dec. 28, 2006

(54) Use selective growth metallization to improve electrical connection between carbon nanotubes and electrodes

(75) Inventors: Shiqun Gu, Vancouver, WA (US); James Elmer, Vancouver, WA (US); Peter A. Burke, Portland, OR (US)

Correspondence Address: LSI LOGIC CORPORATION, 1621 BARBER LANE, MS: D-106, MILPITAS, CA, 95035, US

(73) Assignee: LSI Logic Corporation

(21) Appl. No.: 11/329,849

(22) Filed: Jan. 11, 2006

Related U.S. Application Data
(60) Provisional application No. 60/694,588, filed on Jun. 27, 2005.

(51) Int. Cl. H01L 21/00

(52) U.S. Cl. 438/20

(57) ABSTRACT

Disclosed is a method of making a CNT device such as a memory switch, a field emission display, interconnect wiring, etc. The method includes steps of providing CNTs in contact with an electrode and selectively growing or depositing a layer of metal on top of the CNTs and the electrode. The layer of metal improves the electrical contact between the CNTs and the electrode. If a CNT memory switch is provided, the electrode can be embedded into dielectric or may lie on top of a dielectric substrate. In the case of interconnect wiring, an electrode can be provided embedded in dielectric and a via may be provided to the electrode. CNTs are disposed in the via, and the method provides that metal is selectively grown or deposited in the via, in contact with the CNTs and the electrode, thereby providing good electrical contact between the CNTs and the electrode.

### RELATED APPLICATION (PRIORITY CLAIM)

This application claims the benefit of U.S. Provisional Application Ser. No. 60/694,588, filed Jun. 27, 2005, which is hereby incorporated herein by reference in its entirety.

### BACKGROUND

The present invention generally relates to carbon nanotube technology, and more specifically relates to methods of improving the electrical contact between carbon nanotubes and electrodes.

Carbon nanotube technology is fast becoming a technological area to make an impact in electronic devices. Single-wall carbon nanotubes (CNTs) are quasi-one dimensional nanowires, which exhibit either metallic of semiconducting properties, depending upon their chirality and radius. Single-wall nanotubes have been demonstrated as both semiconducting layers in thin film transistors as well as metallic interconnects between metal layers.

Some examples of applications using CNTs include:

1) Two terminal switch devices for memory: A new technology pioneered by Nantero uses carbon nanotubes as electromechanical switches for non-volatile memory devices. Nantero discovered that 2-terminal switching devices can be made by simply overlapping a metal electrode a discreet distance across nanotubes (CNTs) ends, as shown in FIG. 1, wherein reference numeral 10 identifies a programming electrode, reference numeral 12 identifies a contact electrode, reference numeral 14 identifies CNT, and reference numeral 16 identifies the discreet overlap of the CNT 14 with the programming electrode 10. By applying the appropriate voltage to the nanotubes 14, a nanoscale space is created between the overlapped nanotubes (area 16) and the metal electrode 10, which becomes the switching region. Recently, LSI Logic, the assignee of the present application, and Nantero have co-developed switches with CNTs 14 coated on top of the electrodes 10, 12, as shown in FIG. 2, instead of lying under the electrodes 10, 12, as shown in FIG. 1. In FIG. 2, reference numeral 17 identifies a switching cavity, which may be about 50 nm wide (this dimension is identified with reference numeral 19 in FIG. 2), and reference numeral 21 identifies passivation oxide.

2) Field emission devices: In such devices, as shown in FIG. 3, one end 20 of CNTs 14 is connected to an electrode 10, and a bias 22 is applied between the electrode 10 and a fluorescence screen 24. Because the free end 26 of each of the CNTs 14 has a small diameter and a strong electric field, electrons 28 emit from the end 26 of the CNTs 14 and excite the fluorescence screen 24.

In each of the approaches shown in FIGS. 2 and 3, the CNTs 14 are lying on top of the metal electrode 10. The electrical connection between the CNTs 14 and the electrode 10 is only through the one side contact, and the contact area is typically relatively small. For field emission devices such as is shown in FIG. 3, the electrical conduction between the CNTs 14 and bottom electrode 10 could also be very poor when CNTs 14 are simply lying on top of the electrode 10, due to such minimal surface contact area 30, as shown in FIG. 4 which provides an enlarged view. On the other hand, if any CNT 14 is physically spaced away from the electrode 10 (i.e., not in contact with the electrode 10), then there will be no direct electrical contact between the electrode 10 and CNT 14. When high current is used for the switch, the poor electric conduction between the electrode 10 and CNT 14 could amount to a reliability problem.

### OBJECT AND SUMMARY

An object of an embodiment of the present invention is to provide a method of improving the electrical contact between carbon nanotubes and electrodes.

Briefly, and in accordance with at least one of the foregoing objects, an embodiment of the present invention provides a method of making a carbon nanotube device, where the method includes steps of providing CNTs proximate to an electrode and selectively forming, such as by growing or depositing, a layer of metal on top of the CNTs and the electrode. The layer of metal which is selectively grown or deposited improves the electrical contact between the CNTs and the electrode. The carbon nanotube device can take many different forms, such as, for example, a CNT memory switch, a field emission display, interconnect wiring, etc.

### BRIEF DESCRIPTION OF THE DRAWINGS

The organization and manner of the structure and operation of the invention, together with further objects and advantages thereof, may best be understood by reference to the following description, taken in connection with the accompanying drawing, wherein:

FIG. 1 is a cross-sectional view of a 2-terminal switching device having a CNT/programming electrode overlap;

FIG. 2 is a cross-sectional view of a nonvolatile memory switch where an end of the CNTs overlap a top of an electrode;

FIG. 3 is a schematic diagram of a filed emission device which uses CNT technology;

FIG. 4 is an enlarged view of a portion of FIG. 3, showing the contact area between the end of the CNTs and the electrode;

FIG. 5 is a block diagram which illustrates a method which is in accordance with an embodiment of the present invention;

FIGS. 6, 7a, 7b, 8, 9a, 9b, 10, 11a, 11b, 12, 13a and 13b show a CNT memory switch as it is being made in accordance with the method shown in FIG. 5;

FIG. 14 illustrates a field emission display which is in accordance with an embodiment of the present invention;

FIG. 15 is an enlarged view of a portion of what is shown in FIG. 14, showing an enhanced contact point; and

FIG. 16 illustrates an interconnect which is in accordance with an embodiment of the present invention; and

FIGS. 17 and 18 illustrate a plug fill interconnect as it is being made in accordance with an embodiment of the present invention.

### DESCRIPTION

While the invention may be susceptible to embodiment in different forms, there are shown in the drawings, and herein will be described in detail, specific embodiments of the invention. The present disclosure is to be considered an example of the principles of the invention, and is not intended to limit the invention to that which is illustrated and described herein.

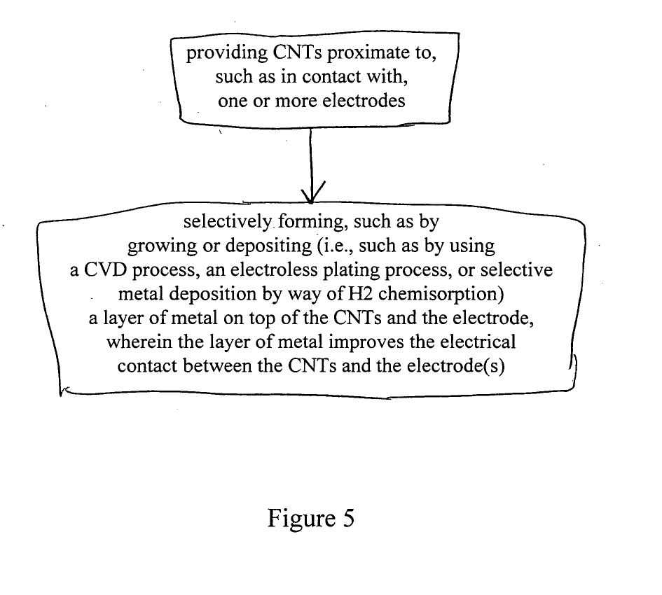

FIG. 5 illustrates a method of making a carbon nanotube device, where the method is in accordance with an embodiment of the present invention. As shown, the method includes steps of providing CNTs proximate to, such as in contact with, an electrode and selectively forming, such as by growing or depositing, a layer of metal on top of the CNTs and the electrode. The layer of metal which is selectively grown or deposited improves the electrical contact between the CNTs and the electrode. The carbon nanotube device can take many different forms, such as, for example, a CNT memory switch, a field emission display, interconnect wiring, etc., and some of these will be described below with reference to FIGS. 6-18.

FIGS. 6, 7A, 7B, 8, 9A, 9B, 10, 11A, 11B, 12, 13A and 13B provide a progression of views that collectively illustrate the forming of a nanotube switch in accordance with the present invention. As shown in FIG. 6, initially an ILD layer 100 is provided having electrodes 102, 104. The electrodes 102, 104 can be any conductive material, including doped poly-Si, contact (e.g., W), or metal/via material (e.g., Al, Cu, TiN, TaN). FIGS. 7A and 7B are cross-sectional views taken along line 7-7 of FIG. 6. As shown in FIG. 7A, the electrodes 102, 104 can be embedded into dielectric 106 either by using a damascene process or by being polished back after a dielectric deposition process. Alternatively, as shown in FIG. 7B, the electrodes 102, 104 can lie on top of the dielectric 106.

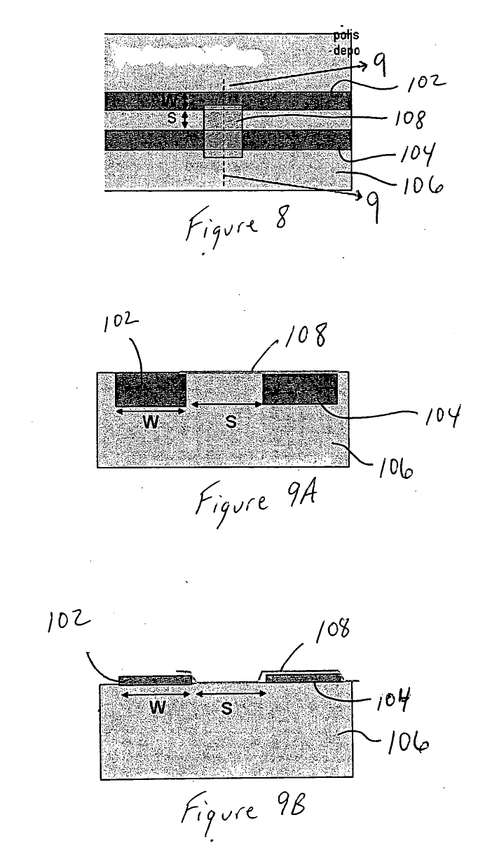

Then, as shown in FIG. 8, CNTs 108 are coated and patterned. FIGS. 9A and 9B are cross-sectional views taken along line 9-9 of FIG. 8, wherein FIG. 9A illustrates the case when the electrodes 102, 104 are embedded in the dielectric 106, and FIG. 9B illustrates the case where the electrodes 102, 104 are provided as being on top of the dielectric 106.

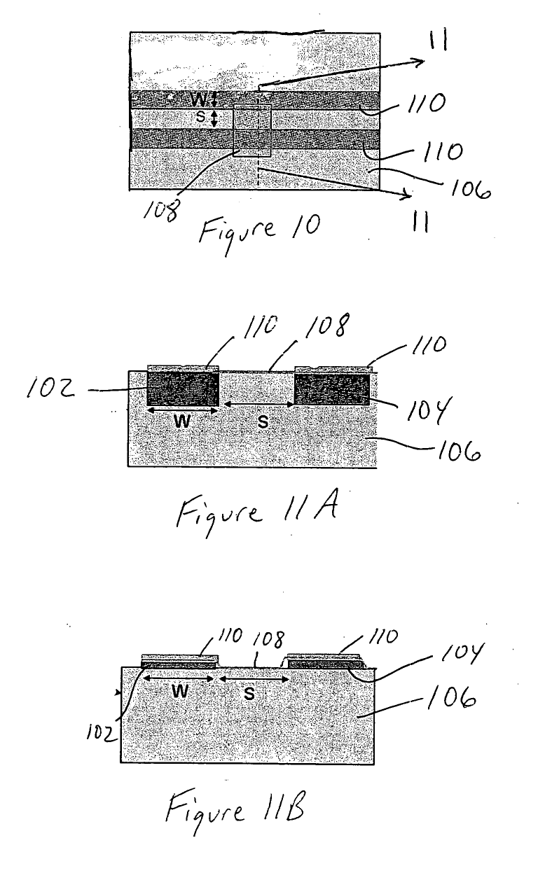

Then, as shown in FIG. 10, a thin metal layer (i.e., 1-20 nm) 110 is formed, such as selectively grown, on top of each electrode 102, 104 but not on the dielectric 106 or the CNTs 108 which span the electrodes 102, 104 on the dielectric 106. FIGS. 11A and 11B are cross-sectional views taken along line 11-11 of FIG. 10, wherein FIG. 11A illustrates the case when the electrodes 102, 104 are embedded in the dielectric 106, and FIG. 11B illustrates the case where the electrodes 102, 104 are provided as being on top of the dielectric 106.

There are several selective growth techniques which can be used, such as:
a) a CVD process, wherein there is epitaxial growth on the area which is only partially a crystal material, and there is no growth on the amorphous area. For example, a metallic-precursor can be used (i.e., on the CNTs, over each electrode), and then metal deposition is grown on the metal electrode, with no growth forming on the insulator (i.e., on the dielectric which is proximate each electrode, or on the CNTs which are on the dielectric and span the electrodes).
b) an electroless plating process: electroless plating is a chemical reduction process which depends upon the catalytic reduction process of metal ions in an aqueous solution (containing a chemical reducing agent) and the subsequent deposition of metal without the use of electrical energy. For example, a thin layer of CoWP, CoB or NiMoP can be plated on top of Cu and the insulator can be left metal free. In other words, Cu can be deposited on the CNTs on locations where it desired to ultimately have a layer of metal, and in no other places (such as on the dielectric). Then, a metal such as CoWP, CoB or NiMoP can be plated on top of the Cu, wherein the insulator is left metal free.
c) Selective metal deposition by way of H2 chemisorption. Example of selective W-CVD on W metal.

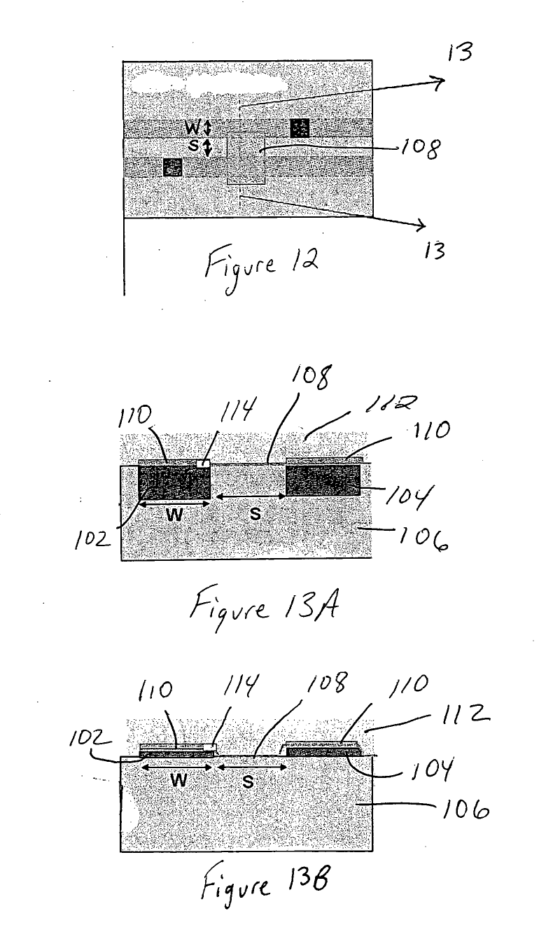

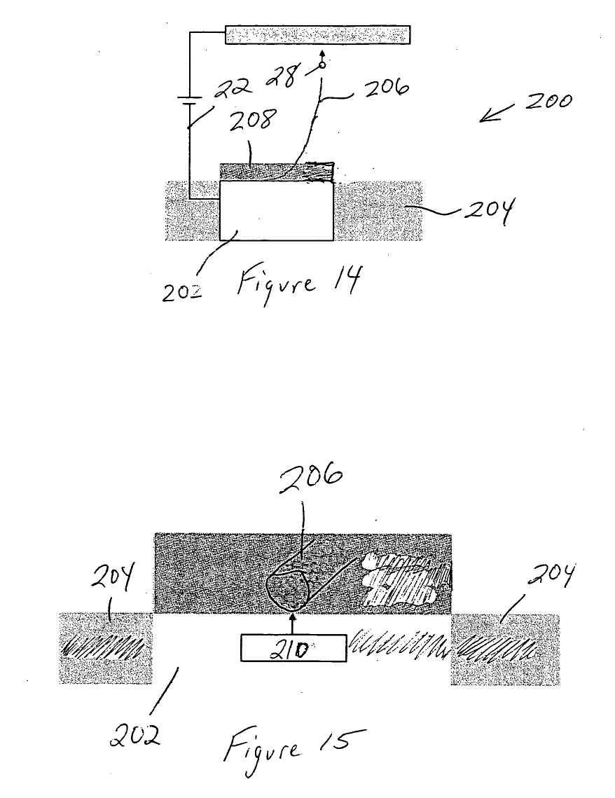

Then, as shown in FIG. 12, the electrodes 102, 104 and CNTs 108 are passivated (i.e., passivation oxide 112 is deposited on the device), contact points 114 are opened, and micro-voids are created for the CNT switches. FIGS. 13A and 13B are cross-sectional views taken along line 13-13 of FIG. 12, wherein FIG. 13A illustrates the case when the electrodes 102, 104 are embedded in the dielectric 106, and FIG. 13B illustrates the case where the electrodes 102, 104 are provided as being on top of the dielectric 106.

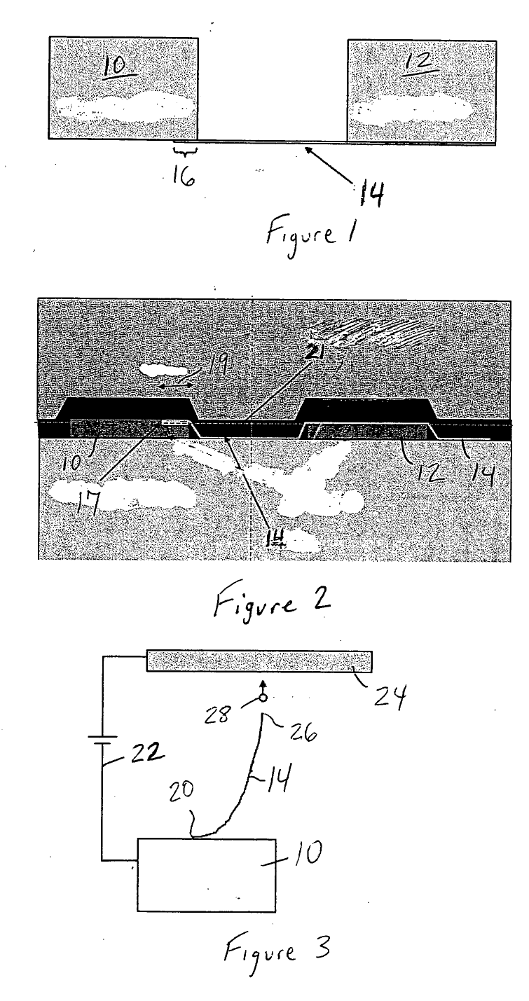

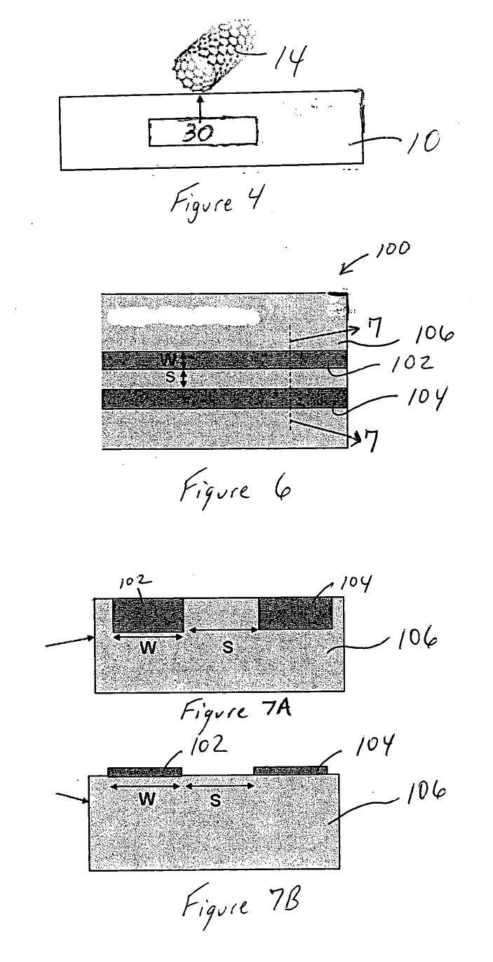

FIG. 14 illustrates another embodiment of the present invention, specifically a field emission display 200. Initially, an electrode 202 is provided embedded in a dielectric 204, for example, CNTs 206 are formed, and a thin layer 208 of metal is selectively grown (such as by using a CVD process or electroless plating process, as described above). In FIG. 14, like in FIG. 3, reference numeral 24 identifies a fluorescence screen, and reference numerals 22 and 28 identify bias and electrons, respectively. The thin layer of metal 208 works to increase the effective electrical contact area 210 between the CNTs 206 and the electrode 202, as shown in FIG. 15, and because a selective growth process is used, there is no metal provided on the insulators 204 which are adjacent the electrode.

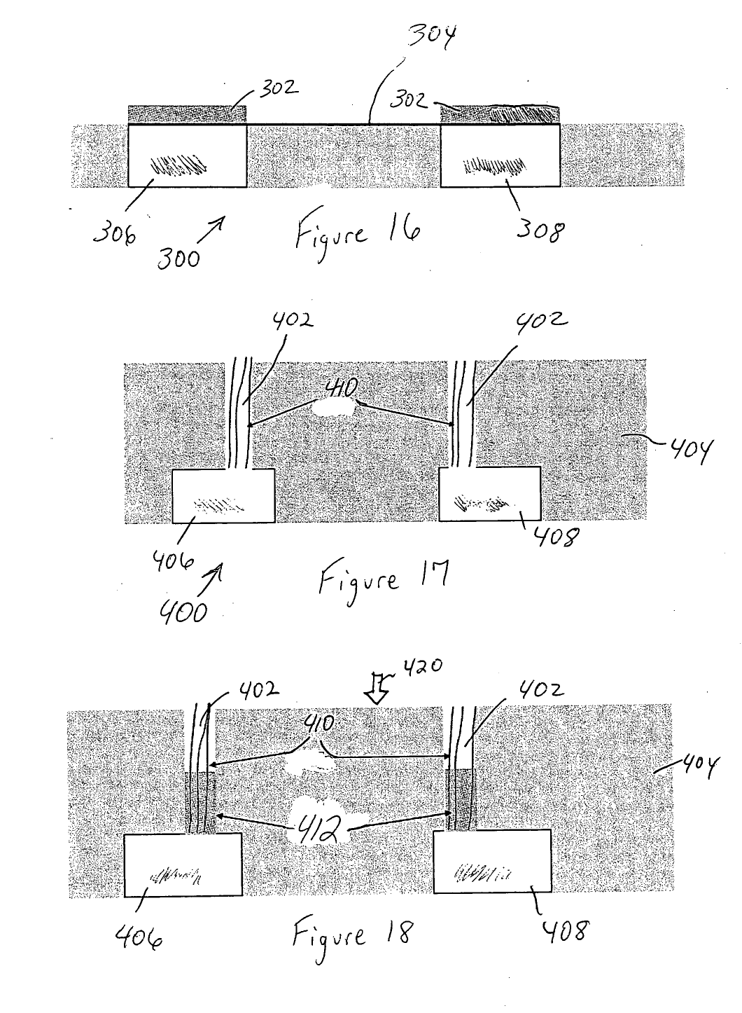

FIG. 16 illustrates yet another embodiment, specifically interconnect wiring, wherein a thin layer of metal 302 can be selectively grown (as described above) on CNTs 304, over two electrodes 306, 308. This may have more flexibility than standard aluminum laser ablation for fuse applications.

FIGS. 17-18 illustrate yet another embodiment, specifically a plug fill interconnect 400, wherein vias 402 are provided in the dielectric 404, ending at the electrodes 406, 408, and CNTs 410 are provided in the vias 402, in contact with the electrodes 406, 408. Then, metal 412 is selectively grown (as described above), thereby providing what is shown in FIG. 18. The selective metal growth in the vias 402 improves the electrical connect between the CNTs 410 and the bottom metal (i.e., the electrodes 406, 408), and reduces the possibility of a void between the CNTs 410 and the electrodes 406, 408, as a result of growing the metal from the bottom up (i.e., starting at the electrodes 406, 408). Advantages of the embodiment shown in FIG. 18 include the fact that the selective growth metal 412 is wrapped around the CNTs 410, which significantly increases the effective contact area between the CNTs 410 and the bottom electrodes 406, 408. Even for CNTs which are not in physical contact with the bottom electrode, the layer of metal 412 which is grown in the vias 402 improves the chance of an effective connection resulting between the CNTs 410 and the electrodes 406, 408. Additionally, while selectively growing the metal, some minor amount of metal may end up being deposited on top of the CNTs, which may help protect the CNTs from plasma damages during the passivation deposition (wherein the passivation deposition step is indicated in FIG. 18 using arrow 420).

The present invention provides a novel method to increase the electric contact area between CNTs and an electrode while maintaining the electrical isolation between electrodes. Specifically, after the CNTs are formed on top of an electrode (either by CNT coating and patterning, or by growth from seeds), a thin metal layer is selectively formed, such as by selective metal growth, on top of the electrode while not forming any metal on the insulator.

While embodiments of the present invention are shown and described, it is envisioned that those skilled in the art may devise various modifications of the present invention without departing from the spirit and scope of the appended claims.

What is claimed is:

1. A method of making a nanotube device, comprising: providing carbon nanotubes proximate an electrode; and forming a layer of metal on the carbon nanotubes and the electrode.

2. A method as recited in claim 1, further comprising providing that the carbon nanotubes are in contact with the electrode.

3. A method as recited in claim 1, wherein the step of forming a layer of metal on the carbon nanotubes and the electrode comprises selectively growing the layer of metal.

4. A method as recited in claim 1, wherein the step of forming a layer of metal on the carbon nanotubes and the electrode comprises forming the layer of metal such that the carbon nanotubes become embedded in the metal.

5. A method as recited in claim 1, wherein the step of forming a layer of metal on the carbon nanotubes and the electrode comprises using a CVD process to form the metal.

6. A method as recited in claim 5, wherein the step of using a CVD process comprises using a metallic-precursor and then depositing metal on the metallic-precursor.

7. A method as recited in claim 1, wherein the step of forming a layer of metal on the carbon nanotubes and the electrode comprises using an electroless plating process.

8. A method as recited in claim 7, wherein the step of using an electroless plating process comprises depositing Cu on the carbon nanotubes on locations where it is desired to ultimately have a layer of metal, and then plating a metal on the Cu.

9. A method as recited in claim 8, wherein the step of plating a metal comprises plating CoWP, CoB or NiMoP on top of the Cu.

10. A method as recited in claim 1, wherein the step of forming a layer of metal on the carbon nanotubes comprises selective metal deposition by way of H2 chemisorption.

11. A method as recited in claim 1, further comprising depositing a passivation oxide on the layer of metal.

12. A method as recited in claim 1, further comprising providing that the electrode is either embedded in dielectric or is disposed on top of dielectric.

13. A method as recited in claim 1, further comprising providing that the electrode is embedded in dielectric, that a via extends through the dielectric to the electrode, and that there are carbon nanotubes in the via, said method further comprising forming metal in the via, in contact with the carbon nanotubes and the electrode.

14. A nanotube device comprising: carbon nanotubes in contact with an electrode; and a layer of metal on the carbon nanotubes and the electrode.

15. A nanotube device as recited in claim 14, wherein the layer of metal is selectively grown.

16. A nanotube device as recited in claim 14, wherein the carbon nanotubes are embedded in the metal.

17. A nanotube device as recited in claim 14, wherein the metal is formed using a CVD process.

18. A nanotube device as recited in claim 14, wherein the metal is formed using an electroless plating process.

19. A nanotube device as recited in claim 14, further comprising a passivation oxide on the layer of metal.

20. A nanotube device as recited in claim 14, wherein the electrode is embedded in dielectric, a via extends through the dielectric to the electrode, there are carbon nanotubes in the via, and there is metal in the via, in contact with the carbon nanotubes and the electrode.

21. A nanotube device as recited in claim 14, wherein the device comprises a carbon nanotube memory switch, a field emission display or interconnect wiring.

22. A nanotube device as recited in claim 14, wherein the metal is formed by selective metal deposition by way of H2 chemisorption.
